(19) United States
(12) Patent Application Publication
(10) Pub. No.: US 2017/0369366 A1
(43) Pub. Date: Dec. 28, 2017

(54) SCRATCH-RESISTANT WINDOWS WITH SMALL POLYCRYSTALS

(71) Applicant: Rubicon Technology, Inc., Bensenville, IL (US)

(72) Inventor: John P. Ciraldo, Elgin, IL (US)

(21) Appl. No.: 15/196,923

(22) Filed: Jun. 29, 2016

Related U.S. Application Data
(63) Continuation of application No. 15/193,868, filed on Jun. 27, 2016.

(51) Int. Cl. C03C 17/245; C03C 17/00; C23C 14/34; C23C 14/00; C23C 14/08

(52) U.S. Cl. CPC C03C 17/245; C23C 14/0036; C23C 14/081; C23C 14/34; C03C 17/002; C03C 2217/214; C03C 2217/78; C03C 2218/154; C03C 2218/155

(57) ABSTRACT

A window has an ion exchange substrate with a top surface. To improve robustness, the top surface has a polycrystalline aluminum oxide film formed from a plurality of crystals. At least 95% of the plurality of crystals in the aluminum oxide film has a largest dimension of no greater than about 10 nanometers. In addition, both the ion exchange substrate and aluminum oxide film are transparent or translucent.

### PRIORITY

This patent application is a continuation of U.S. patent application Ser. No. 15/193,868, filed on Jun. 27, 2016, entitled, “SCRATCH-RESISTANT WINDOWS WITH SMALL POLYCRYSTALS,” attorney docket number 4217/1038, and naming John P. Ciraldo as inventor, the disclosure of which, is incorporated herein, in its entirety, by reference.

### CROSS-REFERENCE TO RELATED APPLICATIONS

This patent application is related to the following patent applications: U.S. patent application Ser. No. 14/101,957, filed on Dec. 10, 2013, entitled, “METHOD OF GROWING ALUMINUM OXIDE ONTO SUBSTRATES BY USE OF AN ALUMINUM SOURCE IN AN ENVIRONMENT CONTAINING PARTIAL PRESSURE OF OXYGEN TO CREATE TRANSPARENT, SCRATCH-RESISTANT WINDOWS,” attorney docket number 4217/1018, and naming Jonathan Levine and John Ciraldo as inventors, and

U.S. patent application Ser. No. 14/101,980, filed on Dec. 10, 2013, entitled, “METHOD OF GROWING ALUMINUM OXIDE ONTO SUBSTRATES BY USE OF AN ALUMINUM SOURCE IN AN OXYGEN ENVIRONMENT TO CREATE TRANSPARENT, SCRATCH-RESISTANT WINDOWS,” attorney docket number 4217/1023, and naming Jonathan Levine and John Ciraldo as inventors.

The disclosures of both above noted patent applications are incorporated herein, in their entireties, by reference.

### BACKGROUND OF THE INVENTION

### 1.0 Field of the Disclosure

Illustrative embodiments relate to a system, method, and device for coating a material (e.g., a substrate) with a layer of aluminum oxide to provide a transparent, scratch-resistant surface.

### 2.0 Related Art

There are many applications for use of glass, including applications in, e.g., the electronics area. Mobile devices, such as cell phones and computers, may employ glass screens configured as a touch screen. Undesirably, these glass screens can be prone to breakage or scratching.

The following patent documents provide informative disclosures: WO 87/02713; U.S. Pat. No. 5,350,607; U.S. Pat. No. 5,693,417; U.S. Pat. No. 5,698,314; and U.S. Pat. No. 5,855,950.

Xinhui Mao et al., in their article titled “Deposition of Aluminum Oxide Films by Pulsed Reactive Sputtering,” J. Mater. Sci. Technol., Vol. 19, No. 4, 2003, describe a pulsed reactive sputtering process that may be used to deposit some compound films, which are not easily deposited by traditional direct current (D.C.) reactive sputtering.

P. Jin et al., in their article “Localized epitaxial growth of α-Al₂O₃ thin films on Cr₂O₃ template by sputter deposition at low substrate temperature,” Applied Physics Letters, Vol. 82, No. 7, Feb. 17, 2003, describe low-temperature growth of α-Al₂O₃ films by sputtering.

### SUMMARY OF ILLUSTRATIVE EMBODIMENTS

In accordance with one embodiment of the invention, a window has an ion exchange substrate with a top surface. To improve robustness, the top surface has a polycrystalline aluminum oxide film formed from a plurality of crystals. At least 95% of the plurality of crystals in the aluminum oxide film has a largest dimension of no greater than about 10 nanometers. In addition, both the ion exchange substrate and aluminum oxide film are transparent or translucent.

Among other things, the ion exchange substrate may include glass, such as boron silicate glass, or aluminum-silicate glass. The substrate and film may have an aggregate Young's Modulus of less than about 350 Gigapascals.

The film may include sapphire. Moreover the film may have a film hardness that is greater than the substrate hardness. The film, which may have a thickness of between 10 nanometers and 10 microns, may be chemically adhered to the top surface of the substrate, or mechanically adhered to the top surface of the substrate. For example, the film may be conformal to top surface of the substrate.

In some embodiments, at least 98 percent of the plurality of crystals may have a maximum dimension that is no greater than about 10 nanometers. In other embodiments, at least 95 percent of the plurality of crystals may have a maximum dimension that is no greater than about 5 nanometers.

In accordance with another embodiment of the invention, a window has a quartz substrate with a top surface. To improve robustness, the top surface has a polycrystalline aluminum oxide film formed from a plurality of crystals. At least 95% of the plurality of crystals in the aluminum oxide film has a largest dimension of no greater than about 10 nanometers. In addition, both the quartz substrate and aluminum oxide film are transparent or translucent.

### BRIEF DESCRIPTION OF THE DRAWINGS

The accompanying drawings, which are included to provide a further understanding of various embodiments, are incorporated in and constitute a part of this specification, illustrate embodiments and together with the detailed description serve to explain the illustrative embodiments of the invention. No attempt is made to show structural details in more detail than may be necessary for a fundamental understanding of illustrative embodiments and the various ways in which it may be practiced. In the drawings:

FIG. 1 is a block diagram of an example of a system for coating a material with a layer of aluminum oxide, the system configured according to illustrative embodiments of the invention;

FIG. 2 is a block diagram of an example of a system for coating a material with a layer of aluminum oxide, the system configured according to illustrative embodiments of the invention;

FIG. 2A schematically shows a top/plan view of window produced in accordance with illustrative embodiments of the invention.

FIG. 2B schematically shows a cross-sectional view of the window of FIG. 2A across line B-B.

FIG. 3 is a flow diagram of an example process for creating an aluminum oxide enhanced substrate, the process performed according to illustrative embodiments of the invention.

### DETAILED DESCRIPTION OF ILLUSTRATIVE EMBODIMENTS

Various features and advantageous details of illustrative embodiments are explained more fully with reference to the non-limiting embodiments and examples that are described and/or illustrated in the accompanying drawings and detailed in the following description. It should be noted that the features in the drawings are not necessarily drawn to scale, and features of one embodiment may be employed with other embodiments as the skilled artisan would recognize, even if not explicitly stated herein. In fact, some features of the incorporated patent applications may be added to illustrative embodiments of the invention as described below.

Descriptions of well-known components and processing techniques may be omitted to not unnecessarily obscure the embodiments. The examples used herein are intended merely to facilitate an understanding of ways in which illustrative embodiments may be practiced and to further enable those of skill in the art to practice various embodiments of the invention. Accordingly, the examples and various embodiments described in this description should not be construed as limiting the scope of the many embodiments. Moreover, it is noted that like reference numerals represent similar parts throughout the several views of the drawings.

The terms “including”, “comprising” and variations thereof, as used in this description, mean “including, but not limited to”, unless expressly specified otherwise.

The terms “a”, “an”, and “the”, as used in this description, means “one or more”, unless expressly specified otherwise.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described may be performed in any order practical. Further, some steps may be performed simultaneously. Moreover, not all steps may be required for every implantation.

When a single device or article is described, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

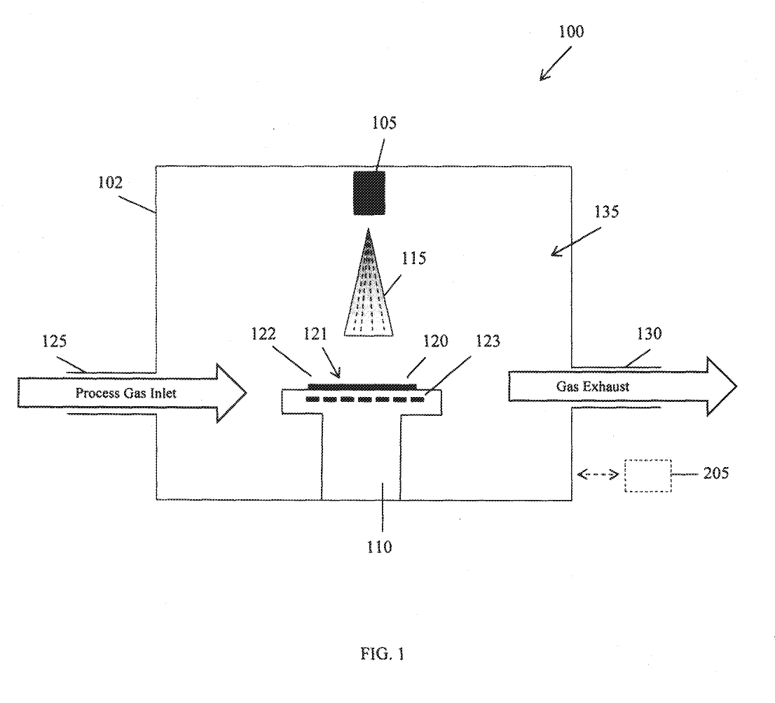

FIG. 1 is a schematic block diagram of an example of a system 100 for coating a material (e.g., a substrate 120, such as glass) with a layer 121 of aluminum oxide, according to illustrative embodiments of the invention. The system 100 may be employed to produce a very hard and superior scratch-resistant surface on glass, or other type of substrates. For example, the substrate may include an ion-exchange glass. The substrate may also be a boron silicate glass, quartz, or plastic. Coating the substrate with aluminum oxide (e.g., sapphire) has been found to produce a high quality product for use in applications where a hard, scratch-resistant surface is beneficial, such as glass windows useable, e.g., in electronic devices or scientific instruments, and the like.

As shown in FIG. 1, system 100 may include an evacuation chamber 102 with partial pressure of process gas 135 created therewithin, including molecular or atomic oxygen. The device 100 may further include an aluminum source 105, a stage 110, a process gas inlet 125, and a gas exhaust 130. The stage 110 may be configured to be heated (or cooled). The stage 110 may be configured to move in any one or more dimensions of 3-D space, including configured to be rotatable, movable in a x-axis, movable in a y-axis and/or movable in a z-axis.

The substrate 120 (e.g., chemically treated glass, such as ion-exchange glass) may be a planar material or a non-planar material, and preferably is transparent or translucent. The substrate 120 may be placed on the stage 110 so that one or more of its surfaces that may be subject to treatment. The substrate 120 may be a boron silicate glass, quartz, or plastic. The substrate may be chemically strengthened prior to coating. In some applications, the substrate 120 may be embodied in multiple dimensions, e.g., to include surfaces oriented in three dimensions that may be coated by the coating process. The aluminum source 105 is configured to produce a controlled deposition beam 115 comprising aluminum atoms and/or aluminum oxide molecules. The deposition beam 115 may be a cloud-like beam. The aluminum source 105 may comprise a sputtering mechanism (e.g., traditional sputtering), or a mechanism as described in incorporated U.S. patent application Ser. No. 14/101,980. In addition, the aluminum source 105 may include a device to heat aluminum. The targeting of the aluminum atoms and/or aluminum oxide molecules may include adjusting the location of the aluminum source 105 and/or adjusting the orientation of the stage 110. Adjusting an orientation or position of the substrate 120 relative to the aluminum ions 115 may adjust an exposure amount of the aluminum ions to the substrate 120. This adjusting may also permit coating of the aluminum oxide to particular or additional sections of the substrate 120.

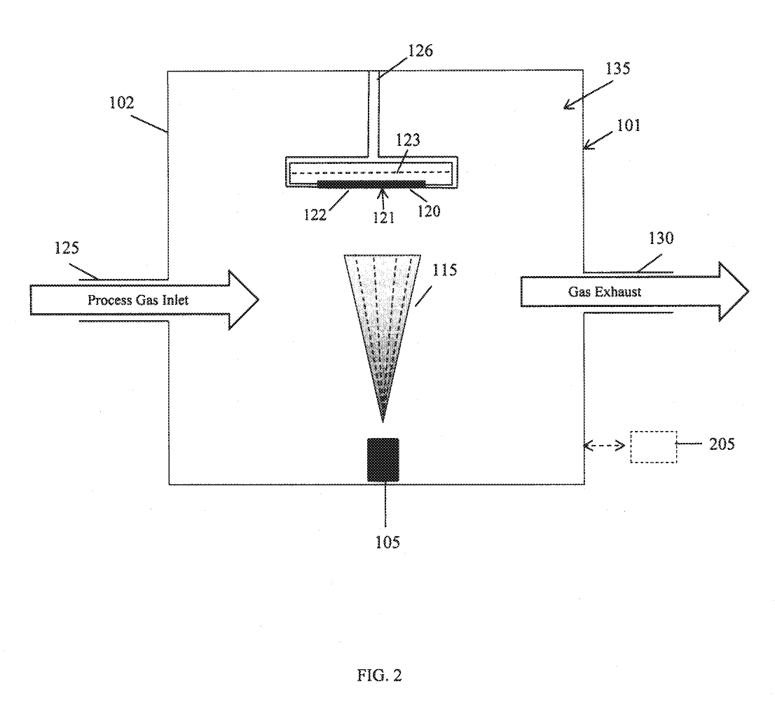

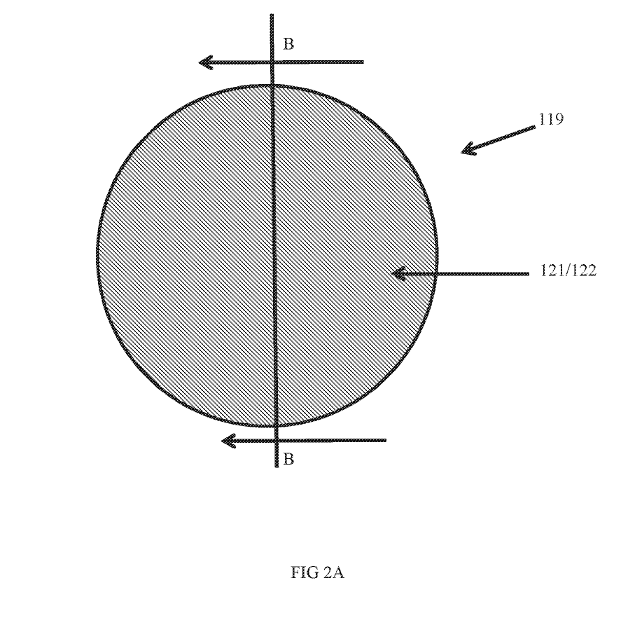

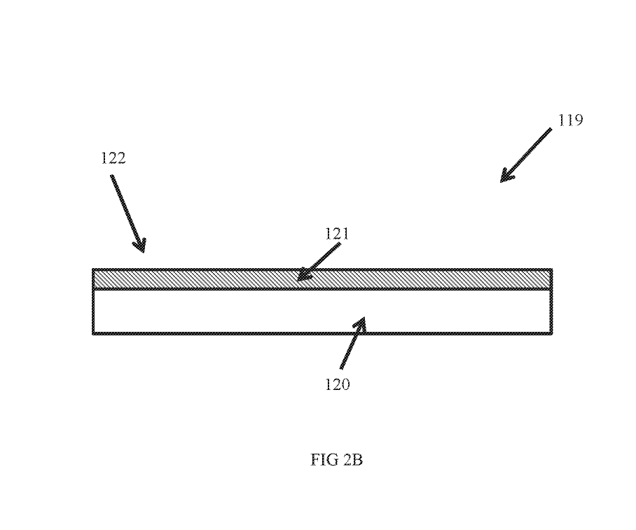

The system 100 may be used to coat a layer of aluminum oxide on the target substrate 120 (e.g., such as glass) to provide a matrix layer (referred to as a “matrix 121” or “layer 121”) having a transparent, scratch resistant surface 122. This coat/layer 121 thus may be considered to form a film on the substrate 120, producing a scratch-resistant window 119. To that end, FIG. 2A schematically shows a plan view of the window 119 in illustrative embodiments of the invention. FIG. 2B schematically shows a cross-sectional view of the window 119 of FIG. 2A across line B-B. As shown, the layer 121 forms a substantially unitary, continuous film across the top of the substrate 120.

In illustrative embodiments, the film/layer 121 is a polycrystalline structure—a plurality of crystals domains. Specifically, as known by those in the art, a polycrystalline structure has local order across the majority of the material (e.g., sixty percent), but lacks that same order across the entire crystal.

The material has plurality of poly-crystals that, as known by those in the art, are known to have sizes—i.e., their largest dimension. In illustrative embodiments, this largest dimension is no greater than about 10 nanometers. For example, this generally unitary film may be formed so that each one of at least 95 percent of the crystals has a largest dimension of no greater than about 10 nanometers. That dimensional limit can be smaller for the 95 percent of crystals. Specifically, each of at least 95 percent of the crystals may have a largest dimension of less than or equal to any one of 9, 8, 7, 6, 5, 4, 3, or 2 nanometers. For example, at least 95 percent of the crystals can have a largest dimension that is less than or equal to about 3 nanometers. In some embodiments, the percentage of crystals having the maximum size can be greater. In that case, at least 96, 97, 98 or even 99 percent of the plurality of crystals can have largest dimensions of less than or equal to about 10, 9, 8, 7, 6, 5, 4, 3, or 2 nanometers, whichever the case may be. For example, 98 percent of the crystals may have largest dimensions of no greater than about 3 nanometers.

In some embodiments, the overall film structure possesses small crystallites combined with amorphous aluminum-oxide to provide mechanical advantages over amorphous or single-crystal films. Such a structure is analogous to a nanoscale concrete where the polycrystalline material serves as the aggregate, strongly bound together by the cement-like amorphous content. Moreover, the small crystal domains provide optical advantages for the final film as the domain sizes have much smaller dimensions that the wavelengths of visible light, effectively mitigating optical interference.

The resultant scratch resistant surface 122 produces the noted window 119, which may be further processed (e.g., by cutting and/or polishing steps) to have applications for a wide variety of products including, e.g., a watch crystal, a camera lens, and e.g., touch screens for use in e.g., mobile phones, tablet computers, scanners (e.g., a grocery store scanner) and laptop computers, where maintaining a scratch-free or break-resistant surface may be of primary importance. The thin window 119 may have a thickness of about 2 mm or less. In some embodiments, the window 119 may have a thickness that is greater than 5 mm in thickness, but less than 6 mm (e.g., about 5.6 mm). The thin window 119 is configured and characterized as having a shatter resistance with a Young's Modulus value that is less than sapphire, which may be less than about 350 gigapascals (GPa). Moreover, it should be understood that, in the case that there are different values for the Young's Modulus based on a testing method or region of material tested (e.g., ion-exchange glass, which may have different values for the surface and the bulk), that the lowest value is the applicable value.

A benefit provided by the resultant matrix 121 at surface 122 includes improved mechanical performance, such as, e.g., improved scratch resistance, greater resistance to cracking compared to currently used materials such as traditional untreated glass, plastic, and the like. Additionally, by using aluminum oxide (e.g., sapphire) coated on glass (e.g., ion exchange glass) rather than an entire aluminum oxide window (i.e., a window comprising all sapphire), the cost may be reduced substantially, making the product available for widespread consumer usage. Moreover, the use of aluminum oxide films, as opposed to full sapphire windows, offers additional cost savings by eliminating the need to cut, grind, and/or polish sapphire, which may be difficult and costly.

According to an embodiment of the invention, a substrate 120, such as, e.g., glass, quartz, or the like, may be placed onto a stage 110, which may be heated within an evacuated chamber 102. Process gases are permitted to flow into the evacuation chamber 102 such that a controlled partial pressure is achieved. This gas may contain oxygen either in atomic or molecular form, and may also contain inert gases such as argon. After achieving the desired partial pressure, a deposition beam comprising energized aluminum atoms and/or aluminum oxide molecules 115 may be introduced such that the substrate 120 is exposed to an aluminum oxide deposition beam 115. Being exposed to oxygen within the evacuation chamber 102, the aluminum atoms may form aluminum oxide (Al₂O₃) molecules, which adhere to the substrate surface 122. The combination thus forms the noted matrix 121, which provides exceptional useful qualities including, e.g., improved scratch resistance and greater resistance to cracking.

If the deposition beam 115 is not sufficiently large enough to homogeneously cover the substrate surface 122, the substrate 120 itself may be moved in the deposition beam, such as, e.g., through movement of the stage 110, which may be controlled to move up, down, left, right, and/or to rotate, to allow an even coating. In some implementations, the aluminum source 105 may be moved. Moreover, the substrate 120 may be heated by a heating device 123 sufficiently to allow mobility of ablated particles on the surface 122 of the substrate 120, allowing for improved quality of the coating agent. The matrix 121 chemically and/or mechanically adheres to the substrate surface 122 to form a bond sufficiently strong enough to substantially prevent delamination of the aluminum oxide (Al₂O₃) with the substrate 120. Accordingly, this process creates a hard and strong surface 122 that is resistant to breaking and/or scratching. In illustrative embodiments, the hardness of the matrix 121/film is greater than the hardness of the substrate 120, thus protecting the surface of the substrate 120 from scratches and the like.

The growth rate of the aluminum oxide (Al₂O₃) layer forming matrix 121 at the surface 122 may be tunable. The growth rate of the aluminum oxide (Al₂O₃) layer forming matrix 121 may be enhanced by reducing the distance between the aluminum source 105 and the substrate 120. The growth rate may be further enhanced by optimizing sputter power, as well as ambient gas pressure and composition.

The substrate 120 may be exposed to the aluminum oxide deposition beam, and the exposure stopped based on a predetermined parameter, such as, e.g., a predetermined time period and/or a predetermined depth of layering of aluminum oxide on the substrate 120 being achieved. The predetermined parameter may include a predetermined amount of aluminum oxide deposited such that the amount is sufficient to achieve a desired amount of scratch resistance, but not thick enough to affect the shatter resistance of the substrate 120. In some applications, the amount of aluminum oxide deposited may have a thickness less than about 1% of the thickness of the substrate 120. Moreover, the amount of aluminum oxide deposited may range between about 10 nm and 10 microns (e.g., 5 microns).

Illustrative embodiments may use a radio frequency (RF) or pulsed direct current (DC) sputtered power source to counteract charge accumulation that may result from the dielectric nature of aluminum oxide. Coated layers 2-3 nanometers to 300 microns thick can be achieved depending on the process parameters and duration.

Process duration can range from several minutes to several hours. By controlling the aluminum atom and/or aluminum oxide flux and oxygen partial pressure, the properties of the coated film (i.e., the aluminum oxide) can be tailored to maximize the films scratch resistance and mechanical adhesion of the grown film. The film on the substrate 120 results in a strong matrix that is very difficult to separate. The film preferably is conformal to the surface of the substrate 120. This conformance characteristic may be useful and advantageous to coat irregular surfaces, non-planar surfaces, or surfaces with deformities. Moreover, this conformance characteristic may result in a superior bond over, for example, a laminate technique, which typically does not adhere well to irregular surfaces, non-planar surfaces, or surfaces with certain deformities.

FIG. 2 is a schematic block diagram of an example of a similar system 101 to form the window 119 according to alternative embodiments of the invention. The system 101 is similar to the system of FIG. 1 and works principally the same way, except that the substrate 120 may be oriented differently, which in this example, is oriented above the aluminum source 105. The deposition beam 115 may be controlled to direct the atoms upwardly towards the suspended substrate 120. Adjusting an orientation or position of the substrate 120 relative to the aluminum atoms 115 may adjust an exposure amount of the aluminum atoms to the substrate 120. This may also permit coating of the aluminum oxide to particular or additional sections of the substrate 120. Traditional sputtering may be employed.

The system of FIG. 2 may also generally illustrate that the relationship of the substrate 120 and the aluminum source 105 might be in any practical orientation. An alternate orientation may include a lateral orientation wherein the substrate 120 and the aluminum source may be laterally positioned relative to each other.

In FIG. 2, the substrate 120 may be held in position by a securing mechanism 126. The securing mechanism 126 may include an ability to move in any axis. Moreover, the securing mechanism 126 may include a heater 123 configured to heat the substrate 120.

The substrate 120 may be exposed to the aluminum and aluminum oxide deposition beam, and the exposure stopped based on a predetermined parameter such as, e.g., a predetermined time period and/or a predetermined depth of layering of aluminum oxide on the substrate 120 being achieved.

As noted, the thin window 119 formed by the systems of FIG. 1 and FIG. 2 to have a thickness of about 2 mm or less. The thin window 119 may be configured and characterized as having a shatter resistance with a Young's Modulus value that is less than that of sapphire, i.e., less than about 350 gigapascals (GPa). In other words, the substrate 120 and top surface film, in this example, have an aggregate Young's Modulus of less than about 350 GPa. Moreover, it should be understood that, in the case that there are different values for the Young's Modulus based on a testing method or region of material tested (e.g., ion-exchange glass, which may have different values for the surface and the bulk), that the lowest value is the applicable value.

In some implementations, the systems 100 and 101 may include a computer 205 to control the operations of the various components of the systems 100 and 101. For example, the computer 205 may control the heater 123 for heating of the aluminum source. The computer may also control the motion of the stage 110 or the securing mechanism 126 and may control the partial pressures of the evacuation chamber 102. The computer 205 may also control the tuning of the gap between the aluminum source and the substrate 120. The computer 205 may control the amount of exposure duration of the deposition beam 115 with the substrate 120, perhaps based on, e.g., a predetermined parameter(s) such as time, or based on a depth of the aluminum oxide formed on the substrate 120, or amount/level of pressure of oxygen, or any combination therefore. The gas inlet 125 and gas outlet may include valves (not shown) for controlling the movement of the gases through the systems 100 and 200. The valves may be controlled by computer 205. The computer 205 may include a database for storage of process control parameters and programming.

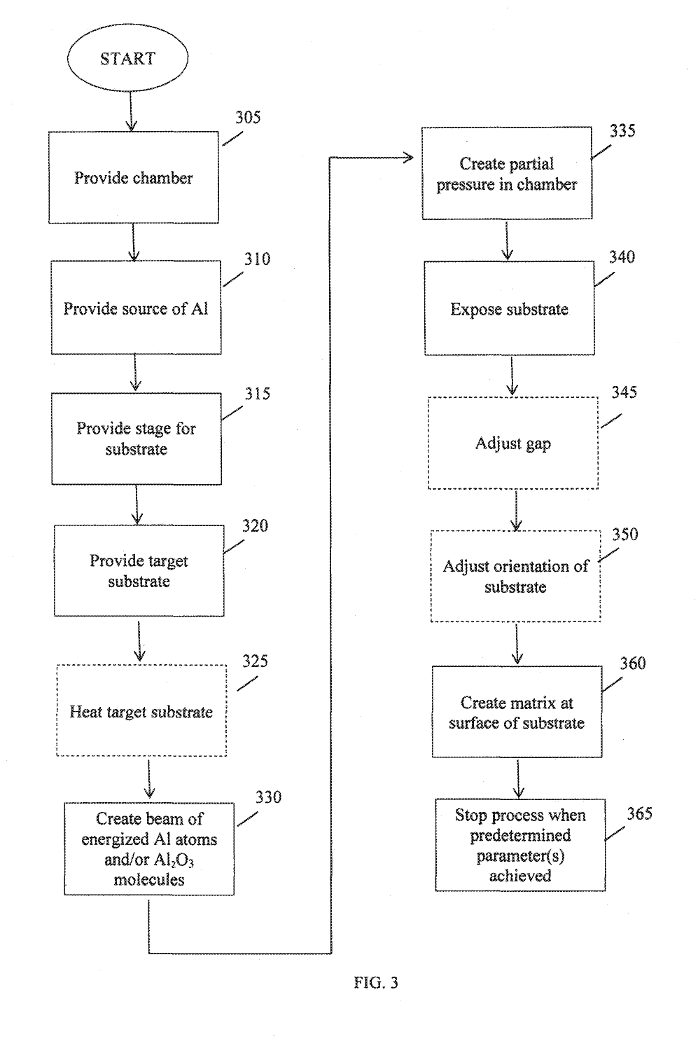

FIG. 3 is a flow diagram of an illustrative process of creating the window 119 of FIGS. 2A and 2B. The process of FIG. 3 may include a traditional type of sputtering, and may form the film 121 on one or both surfaces of the underlying substrate 120. The process of FIG. 3 may be used in conjunction with the systems 100 and 101. At step 305, a chamber, e.g., evacuation chamber 102, may be provided that is configured to permit a partial pressure to be created therein, and configured to permit a target substrate 120 such as, e.g., glass or boron silicate glass to be coated. At step 310, a source of aluminum 105 may be provided that enables energized aluminum atoms 115 to be generated in the evacuation chamber 102. This may comprise a sputtering technique. At step 315, a support securing mechanism 126 or stage such as, e.g., stage 110, may be configured within the chamber 102, depending on the type of system employed. The stage 110 and/or securing mechanism 126 may be configured to be rotatable. The stage 110 and securing mechanism 126 may be configured to be moved in an x-axis, a y-axis and a z-axis.

At step 320, a target substrate 120 having one or more surfaces such as, e.g., glass, borosilicate glass, aluminum-silicate glass, plastic, or yttria-stabilized zirconia (YSZ), may be placed on the stage 110, or alternatively by the securing mechanism 126. At optional step 325, the target substrate 120 may be heated. At step 330, a deposition beam 115 may be created which comprises aluminum atoms and/or aluminum oxide molecules. At step 335, a partial pressure may be created within the chamber. This may be achieved by permitting oxygen to flow into the evacuation chamber 102. At step 340, the substrate 120 is exposed to the deposition beam 115 of aluminum atoms and/or aluminum oxide molecules to coat the substrate 120. The exposure may be based on one or more predetermined parameter(s) such as, e.g., a depth of the aluminum oxide being formed on the target substrate surface(s), time duration, or a pressure level of the oxygen in the evacuation chamber 102, or combinations thereof. The aluminum atoms and aluminum oxide molecules may form the deposition beam 115 directed towards the target substrate 120.

At optional step 345, a gap or distance between the aluminum source 105 and the target substrate 120 may be adjusted to increase or decrease a rate of coating the target substrate 120. At optional step 350, the target substrate 120 may be re-positioned by adjusting the orientation of the stage 110, or adjusting the orientation of the securing mechanism 126. The stage 110 and/or securing mechanism 126 may be rotated or moved in any axis. At step 360, a matrix 121 may be created at one or more surfaces of the target substrate 120 as the aluminum atoms and aluminum oxide molecules coat and bond with the one or more surfaces of the substrate 120. At step 365, the process may be terminated when one or more predetermined parameter(s) are achieved such as time, or based on a depth/thickness of the aluminum oxide formed on the substrate 120, or amount/level of pressure of oxygen, or any combination therefore. Moreover, a user may stop the process at any time.

The process of FIG. 3 produces the noted window 119, which preferably is lightweight, and has substantial resistance to breakability and scratches. In illustrative embodiments, the window 119 has a thickness of about 2 mm or less, although some embodiments may form the window 119 to have a greater thickness, such as those used in grocery store scanners (e.g., point of sale scanners), which may be more than 5.5 mm thick, or dozens of mm thick. The window 119 may be configured and characterized as having a shatter resistance with a Young's Modulus value that is less than that of sapphire, i.e., less than about 350 gigapascals (GPa). Moreover, it should be understood that, in the case that there are different values for the Young's Modulus based on a testing method or region of material tested (e.g., ion exchange glass which may have different values for the surface and the bulk), that the lowest value is the applicable value. The window 119 produced by the process of FIG. 3 may be used to produce transparent thin windows including, e.g., watch crystals, lenses, touch screens in, e.g., mobile phones, smart phones, tablet computers, and laptop computers, where maintaining a scratch-free or break-resistant surface may be of primary importance. As such, the window 119 should be transparent at least to visible light. The process also may be used on translucent types of substrate materials.

The steps of FIG. 3 may be performed by or controlled by a computer, e.g., computer 205 that is configured with software programming to perform the respective steps. The computer 205 may be configured to accept user inputs to permit manual operations of the various steps.

While the description includes examples, those skilled in the art will recognize that illustrative embodiments can be practiced with modifications in the spirit and scope of the appended claims. These examples are merely illustrative and are not meant to be an exhaustive list of all possible designs, embodiments, applications or modifications of various embodiments.

1. A window comprising:
a silicate glass substrate having a top surface; and
a polycrystalline aluminum oxide film on the top surface of the silicate glass substrate, the aluminum oxide film comprising a plurality of crystals,
at least 95% of the plurality of crystals in the film having a largest dimension of no greater than about 10 nanometers,
the silicate glass substrate being transparent or translucent,
the aluminum oxide film being transparent or translucent.

2. (canceled)

3. The window as defined by claim 1 wherein the silicate glass substrate comprises boron silicate glass, or aluminum-silicate glass.

4. The window as defined by claim 1 wherein the substrate and film have an aggregate Young's Modulus of less than about 350 Gigapascals.

5. The window as defined by claim 1 wherein the film comprises sapphire.

6. The window as defined by claim 1 wherein the film has a film hardness, the substrate having a substrate hardness, the film hardness being greater than the substrate hardness.

7. The window as defined by claim 1 wherein the film has a thickness of between 10 nanometers and 10 microns.

8. The window as defined by claim 1 wherein the film is chemically adhered to the top surface of the substrate.

9. The window as defined by claim 1 wherein the film is mechanically adhered to the top surface of the substrate.

10. The window as defined by claim 1 wherein the film is conformal to top surface of the substrate.

11. The window as defined by claim 1 wherein at least 98 percent of the plurality of crystals have a maximum dimension that is no greater than about 10 nanometers.

12. The window as defined by claim 1 wherein at least 95 percent of the plurality of crystals have a maximum dimension that is no greater than about 5 nanometers.

13. A window comprising:
a substrate means having a non-natural, chemically altered crystal lattice structure, the substrate means having a top surface; and
means for resisting scratches positioned on the top surface of the substrate means, the resisting means comprising polycrystalline aluminum oxide with a plurality of crystals, at least 95 percent of the plurality of crystals having a maximum dimension that is no greater than about 10 nanometers,
the substrate means being transparent or translucent,
the resisting means being transparent or translucent.

14. The window as defined by claim 13 wherein the substrate means comprises an ion-exchange substrate.

15. The window as defined by claim 14 wherein the substrate means comprises glass.

16. The window as defined by claim 14 wherein the substrate means comprises boron silicate glass, or aluminum-silicate glass.

17. The window as defined by claim 13 wherein the resisting means comprises sapphire.

18. The window as defined by claim 13 wherein the resisting means is conformal to top surface of the substrate.

19. A window comprising:
a quartz substrate having a top surface; and
a polycrystalline aluminum oxide film on the top surface of the quartz substrate, the aluminum oxide film comprising a plurality of crystals,
at least 95% of the plurality of crystals in the film having a largest dimension of no greater than about 10 nanometers,
the substrate being transparent or translucent,
the aluminum oxide film being transparent or translucent.

20. The window of claim 19 wherein the aluminum oxide comprises sapphire.
